(19) United States
(12) Patent Application Publication
(10) Pub. No.: US 2019/0296406 A1
(43) Pub. Date: Sep. 26, 2019

(54) IN-SITU ELLIPSOMETRY FOR ELECTRIC VEHICLE BATTERY CELL LITHIUM PLATING CHARACTERIZATION

(71) Applicant: SF Motors, Inc., Santa Clara, CA (US)

(72) Inventor: Brennan Campbell, Santa Clara, CA (US)

(21) Appl. No.: 16/012,965

(22) Filed: Jun. 20, 2018

Related U.S. Application Data
(60) Provisional application No. 62/646,990, filed on Mar. 23, 2018.

(51) Int. Cl. H01M 10/48; H01M 4/66; H01M 4/587; H01M 10/44; H01M 10/0525; H02J 7/00; G01N 21/21; G01B 11/06; G01R 31/36

(52) U.S. Cl. CPC H01M 10/48; H01M 4/661; H01M 4/587; H01M 4/664; H01M 10/44; H01M 2220/20; H02J 7/0021; G01N 21/211; G01B 11/0641; G01R 31/3648; H01M 10/0525

(57) ABSTRACT

Systems and methods to evaluate lithium plating on anodes of battery cells are provided. A battery cell can include an aluminum layer, a cathode in contact with the aluminum layer, an anode formed from a powder-based, porous material, a separator layer in contact with the cathode and the anode to electrically insulate the cathode from the anode, and a transparent conductor layer electrically coupled with the anode. A light source can direct polarized light through the transparent conductor layer of the battery cell toward the anode to cause the anode to reflect the polarized light to produce reflected light. A detector can receive the reflected light and can generate an ellipsometry measurement based on the reflected light. A charging circuit can charge the battery cell while the light source directs the polarized light through the transparent conductor layer of the battery cell toward the anode of the battery cell.

### CROSS-REFERENCE TO RELATED APPLICATIONS

The present application claims priority under 35 U.S.C. § 119 U.S. Provisional Patent Application 62/646,990, filed Mar. 23, 2018 and titled “IN-SITU ELLIPSOMETRY FOR ELECTRIC VEHICLE BATTERY CELL LITHIUM PLATING CHARACTERIZATION,” which is incorporated herein by reference in its entirety.

### BACKGROUND

Electric vehicles such as automobiles can include on-board battery cells or battery packs to power the electric vehicles. Batteries can have a limited operational life and can require recharging when depleted.

### SUMMARY

At least one aspect of this disclosure is directed to a system to evaluate lithium plating on anodes of battery cells. The system can include a battery cell having an aluminum layer, a cathode in contact with the aluminum layer, an anode formed from a powder-based, porous material, a separator layer in contact with the cathode and the anode to electrically insulate the cathode from the anode, and a transparent conductor layer electrically coupled with the anode. The system can include a light source to direct polarized light at a first angle with respect to a surface of the anode through the transparent conductor layer of the battery cell toward the anode to cause the anode to reflect the polarized light to produce reflected light directed at a second angle with respect to the surface of the anode. The system can include a detector to receive the reflected light and to generate an ellipsometry measurement based on the reflected light. The system can include a charging circuit to charge the battery cell while the light source directs the polarized light through the transparent conductor layer of the battery cell toward the anode of the battery cell.

At least one other aspect of this disclosure is directed to a method of analyzing lithium plating on anodes of battery cells. The method can include providing a battery cell having an aluminum layer, a cathode in contact with the aluminum layer, an anode formed from a powder-based, porous material, a separator layer in contact with the cathode and the anode to electrically insulate the cathode from the anode, and a transparent conductor layer electrically coupled with the anode. The method can include directing polarized light from a light source at a first angle with respect to a surface of the anode through the transparent conductor layer of the battery cell toward the anode to cause the anode to reflect the polarized light to produce reflected light directed at a second angle with respect to the surface of the anode. The method can include receiving, by a detector, the reflected light. The method can include generating, by the detector, an ellipsometry measurement based on the reflected light. The method can include charging, by a charging circuit, the battery cell while the light source directs the polarized light through the transparent conductor layer of the battery cell toward the anode of the battery cell.

At least one other aspect of this disclosure is directed to a method. The method includes providing a system to detect lithium plating on anodes of battery cells. The battery cell can have an aluminum layer, a cathode in contact with the aluminum layer, an anode formed from a powder-based, porous material, a separator layer in contact with the cathode and the anode to electrically insulate the cathode from the anode, and a transparent conductor layer electrically coupled with the anode. A light source can direct polarized light at a first angle with respect to a surface of the anode through the transparent conductor layer of the battery cell toward the anode to cause the anode to reflect the polarized light to produce reflected light directed at a second angle with respect to the surface of the anode. A detector can receive the reflected light, and can generate an ellipsometry measurement based on the reflected light. A charging circuit can charge the battery cell while the light source directs the polarized light through the transparent conductor layer of the battery cell toward the anode of the battery cell.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 depicts a block diagram of an example system to characterize lithium plating on anodes of battery cells, according to an illustrative implementation;

FIG. 2 depicts a detailed view of components of the system of FIG. 1, according to an illustrative implementation;

FIG. 3 depicts an example spectroscopic graph that can be produced by the system of FIG. 1, according to an illustrative implementation;

FIG. 4 is a block diagram depicting a cross-sectional view of an example battery pack for holding battery cells in an electric vehicle, according to an illustrative implementation;

FIG. 5 is a block diagram depicting a top-down view of an example battery pack for holding for battery cells in an electric vehicle, according to an illustrative implementation;

FIG. 6 is a block diagram depicting a cross-sectional view of an example electric vehicle installed with a battery pack, according to an illustrative implementation;

FIG. 7 is a flow diagram depicting an example method of characterizing lithium plating on anodes of battery cells, according to an illustrative implementation; and

FIG. 8 is a flow diagram depicting an example method of characterizing lithium plating on anodes of battery cells, according to an illustrative implementation.

Following below are more detailed descriptions of various concepts related to, and implementations of, methods, apparatuses, and systems for detecting or characterizing lithium plating on anodes of battery cells for electric vehicles. The various concepts introduced above and discussed in greater detail below may be implemented in any of numerous ways, as the described concepts are not limited to any particular manner of implementation.

### DETAILED DESCRIPTION

A battery pack can be installed in and used to power in electric vehicles. For example, such a battery pack can include a plurality of rechargeable lithium ion battery cells. The battery cells may develop lithium plating as a result of charging under certain environmental conditions. It can be difficult to characterize such lithium ion plating and to determine the environmental conditions that result in the lithium ion plating.

Systems and methods described herein relate to evaluating or detecting lithium plating of battery cells for battery packs that can provide power to electric vehicles (“EVs”). Battery packs, which can be referred to herein as battery modules, can include lithium ion battery cells. Lithium ion battery cells can include a positive electrode referred to as a cathode and a negative electrode referred to as an anode. When such a battery cell is charged, the induced electric field can force lithium ions to move from the cathode to the anode. Then, under normal operating conditions, the lithium ions can move back to the cathode when the battery is discharged and release energy in the process. However, under certain conditions, the lithium ions may instead form solid metal deposits that result in lithium plating on the anode. This can decrease the amount of lithium available for the intended charge-discharge process, resulting in reduced performance of the battery. Detecting and characterizing this type of lithium plating can be a complex and time-consuming task.

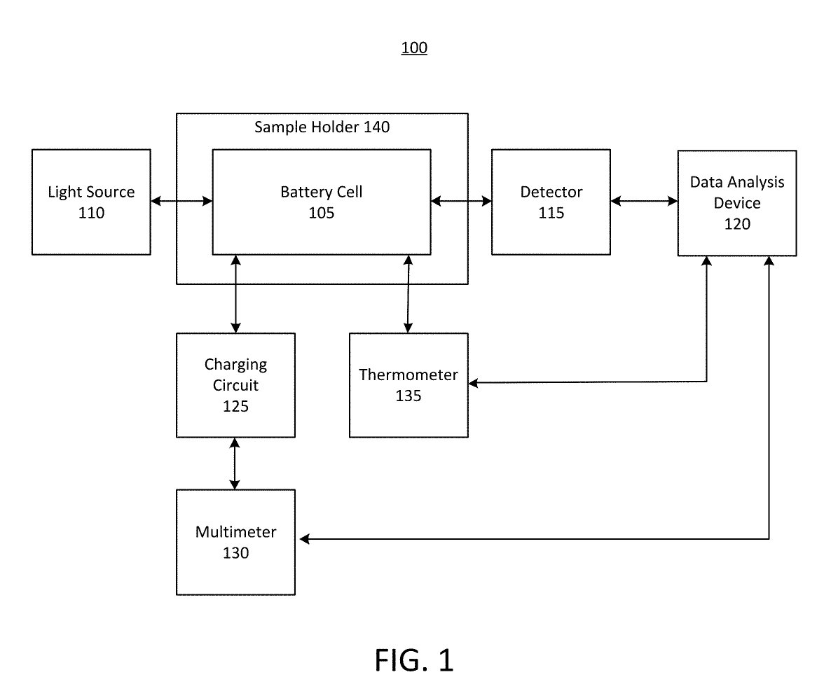

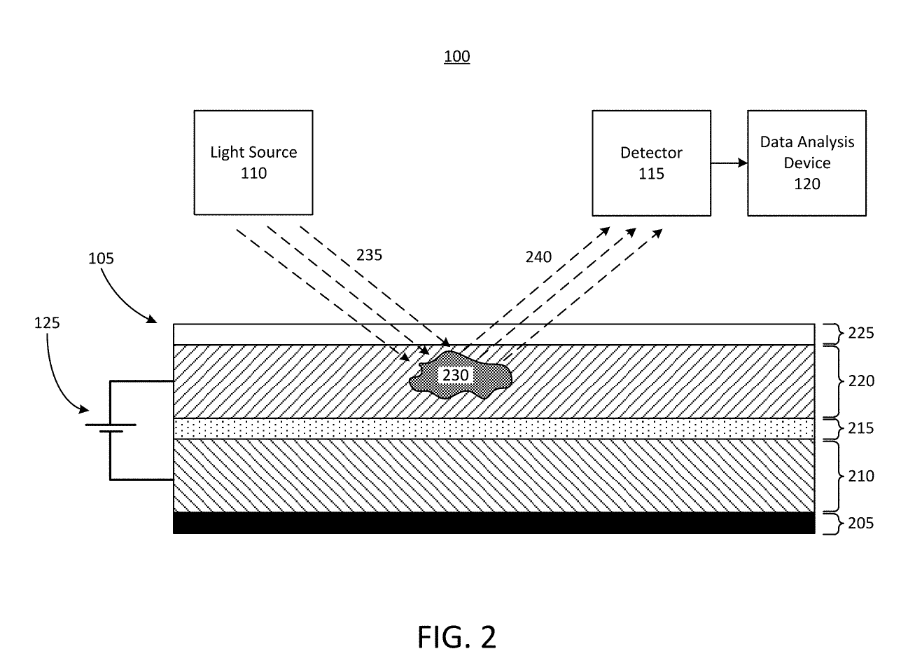

FIG. 1 depicts a block diagram of an example system 100 to characterize lithium plating on anodes of battery cells, according to an illustrative implementation. The system 100 can include at least one battery cell 105, at least one light source 110, and at least one detector 115. The battery cell 105 can be contained within at least one sample holder 140. The system 100 can include at least one analysis device 120 coupled with the detector 115. The system can also include a charging circuit 125 and a thermometer 135 each coupled with the battery cell 105. A multimeter 130 can be coupled with the charging circuit 125. FIG. 2 depicts a detailed view of components of the system 100 of FIG. 1, according to an illustrative implementation. That is, FIG. 2 depicts a particular exemplary arrangement of the battery cell 105, the light source 110, the detector 115, the analysis device 120, and the analysis device 120 shown in FIG. 1.

FIG. 2 also depicts an example implementation for the battery cell 105, which can be formed from a layered stack of materials, including an aluminum layer 205 that may form at least part of a housing or a terminal for the battery cell 105. A cathode 210 can be coupled with the aluminum layer 205. The battery cell 105 can also include an anode 220 that is separated from the cathode 220 by a separator 215. The battery cell 105 can include a transparent conductor 225 in contact with the anode 220. The transparent conductor 225 can be electrically coupled with the anode 220. The transparent conductor can be formed, for example, from fluorinated tin oxide or any other material that is electrically conductive and at least partially transparent to light. The charging circuit 125 is electrically coupled with the cathode 210 and the anode 220.

The battery cell 105 can have a variety of shapes and sizes. For example, the battery cell 105 can be substantially cylindrical, with each layer of the battery cell 105 (i.e., the aluminum layer 205, the cathode 210, the separator 215, the anode 220, and the transparent conductor layer 225) each having a substantially circular cross-sectional shape. The battery cell 105 can have a diameter in the range of about 15 millimeters to about 25 millimeters. The battery cell 105 can have a thickness (i.e., a total distance from the aluminum layer 205 to the transparent conductor layer 225) in the range of about 2 millimeters to about 4 millimeters. For example, the battery cell 105 can have a diameter of 20 millimeters and a thickness of 3.2 millimeters. The battery cell 105 can also have other dimensions outside these ranges. For example the diameter can be 18-24 millimeters and the thickness can be from 2-4 millimeters. Other ranges are possible, such as significantly increased thickness of 65-75 millimeters, for example.

The cathode 210 can be formed from a lithium metal oxide. The anode 220 can be formed from graphite. The separator 215 can be formed from an electrically insulating material, such that the position of the separator 215 between the cathode 210 and the anode 220 electrically isolates the cathode 210 from the anode 220. Other materials are possible for the 215, such as any material capable of isolating the cathode 210 from the anode 220. The charging circuit 125 can charge the battery cell 105. For example, the charging circuit 125 may itself be a rechargeable battery coupled with the battery cell 105 with opposite polarity such that discharging of the charging circuit 125 causes charging of the battery cell 105. The charging circuit 125 can receive power from a power source, such as an electrical outlet. The charging circuit 125 can include any circuitry (such as one or more filters and/or one or more transformers) capable of converting the received power to an electrical signal configured to charge the battery cell 105. During the process of charging the battery cell 105 via the charging circuit 125, the charging circuit 125 can apply a charge across the cathode 210 and the anode 220 to cause lithium ions to move from the cathode to the anode, where they can be stored until the battery cell 105 is discharged.

Lithium plating of the anode 220 can occur as a result of suboptimal environmental charging conditions, such as cold ambient temperatures that may exist during the charging process. Lithium plating of the anode 220 can also occur as a result of overcharging of the battery cell 105. Overcharging can refer to a condition in which an amount of charge accumulated across the separator 215 (i.e., between the cathode 210 and the anode 220) exceeds a threshold amount. Overcharging can also refer to a condition in which a rate at which charge is delivered to the battery cell 105 by the charging circuit 125 exceeds a threshold rate. The lithium deposit 230 shown on the anode 220 can be formed as a result of such a lithium plating process that can occur under a variety of environment or electrical charging conditions. The lithium deposit 230 can have a thickness in the range of five nanometers to 25 microns.

To prevent lithium deposits such as the lithium deposit 230 from forming, it can be useful to understand the characteristics of the lithium deposit 230, as well as the types of charging conditions (e.g., environmental conditions or electrical conditions) under which the lithium deposit 230 forms on the anode 220. For example, this information can allow a user to determine the range of charging conditions that should be used to avoid the formation of the lithium deposit 230, as well as the decreased performance of the battery cell 105 that can coincide with its formation. It can be a technical challenge to convey these characteristics while the battery cell 105 is charging. To address this challenge, this disclosure provides systems and methods that can detect lithium deposits such as the lithium deposit 230, and can also characterize the lithium deposit 230 with respect to its shape, morphology, prominence, microstructure, and other characteristics. The disclosed techniques can also allow for a form of spectral fingerprinting, from which a library can be built attributing features of the resulting spectrum to the type of lithium deposit 230 formed during the charging process. This can serve as a technique to analyze destructive lithium metal outgrowths such as the lithium deposit 230 and can enhance related anode degradation studies in lithium ion batteries such as the battery cell 105.

Referring again to FIGS. 1 and 2, among others, the system 100 can use ellipsometry techniques to detect and characterize the lithium deposit 230 on the anode 220 of the battery cell 105. For example, the light source 110 and the detector 115 together can form an ellipsometer to detect and characterize the lithium deposit 230. The light source 110 and detector 115 can identify or characterize the thickness and material properties of thin films. For example, the light source 110 can produce polarized light. The light produced by the light source 110 can be passed through a polarizer, which can give the light a specific angle. The polarizer can be included as an integral component of the light source 110. The reflected light then has an altered phase angle, which can be captured by the detector 115. As described herein the light source 110 and detector 115 can also be used to detect or characterize the lithium deposit 230 formed on the anode 220, which may be a powder-based, porous material such as graphite. One advantage of the system 100 is that it can distinguish between different morphologies and microstructures of the lithium deposit 230, for example to determine whether the lithium deposit 230 is mossy or dendritic, among other characteristics. In addition, the system 100 can detect and characterize the lithium deposit 230 when the battery cell 105 is in-situ (e.g., installed in a configuration similar to that intended for actual use, rather than strictly for an experimental setup). As an in-situ technique, the system 100 can screen different electrolytes and electrode chemistries in lithium ion batteries similar to the battery cell 105 based on the prominence and morphology or microstructure of lithium metal platings, such as the lithium deposit 230.

The light source 110 and the detector 115 can be powered on, and the battery cell 105 can be positioned with respect to the light source 110 and the detector 115 in a manner that allows light from the light source 110 to be directed at the anode 220 such that the lithium deposit 230 on the anode 220 can be detected and/or characterized. One example arrangement for such a setup is illustrated in FIG. 2. The battery cell 105 can be held in place by the sample holder 140, which may be or may include a chamber configured to contain and secure the battery cell 105 in a steady position at a desired orientation with respect to the light source 110 and the detector 115. For example, the battery cell 105 can be positioned within the sample holder 140 such that the transparent conductor 225 is facing an optical output of the light source 110. The light source 110 can be operated continuously such that polarized light, illustrated by the broken lines 235, from the light source 110 is directed towards the anode 220 through the transparent conductor 225 as the battery cell 105 is charged, over charged, or discharged. The optical signal or other output from the light source 110 can include polarized light. The polarized light can include visible light, or can include light in the infrared or ultraviolet spectrum. The polarized light produced by the light source 110 can also include broad spectrum polarized light.

While the light source 110 directs the polarized light 235 at the anode 220 of the battery cell 105, the battery cell 105 can be charged, over charged, or discharged under a variety of electrical and environmental conditions, which may include different ambient temperatures, different currents or voltages applied by the charging circuit 210, and different electrical loads used to discharge the battery cell 105. The light source 110 can direct the polarized light 235 at various points along the length of the anode 220. For example, the precise location of the lithium deposit 230 may not be known and may not be readily apparent to a user of the system 100 before the system 100 is used to detect the lithium deposit 230. In addition, there can be more than one lithium deposit similar to the lithium deposit 230, and it may be useful to detect and characterize these additional lithium deposits on the battery cell 105 as well. Therefore the light source 110 can scan the polarized light 235 along a length of the anode 220 to increase a probability that the polarized light 235 will contact any lithium deposits such as the lithium deposit 230 that may be present on the anode 220.

The anode 220 can reflect the polarized light to produce reflected light (illustrated by the broken lines 240). The detector 115 can receive the reflected light 240 during operation of the light source 110. The detector 115 can include any device capable of detecting the reflected light 240 and producing output data corresponding to the reflected light 240. For example, the data may indicate a wavelength, a frequency, or a polarization of the reflected light. The detector 115 can produce the output data with reference to characteristics (such as wavelength, frequency, polarization, or position) of the polarized light 235 that corresponds to the reflected light 240. For example, characteristics of the polarized light 235 may vary over time, as the light source changes the position, the wavelength, the frequency, or the polarization of the polarized light 235. The detector 115 can produce output data that correlates the characteristics of the polarized light 235 with those of the reflected light 240 over time.

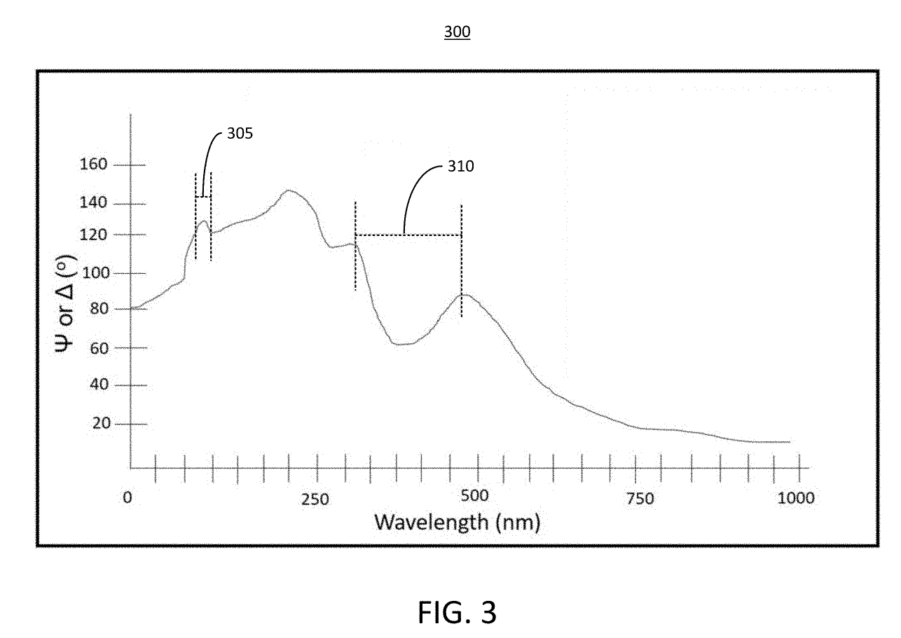

The analysis device 120 can receive the output data from the detector 115. The analysis device 120 can be or can include a data processing system with one or more processors and memory to process the output of the detector 115 to produce at least one ellipsometry measurement. For example, the ellipsometry measurement can relate to any change of polarization of the reflected light 240 relative to the polarized light 235. The analysis device 120 may store one or more models and can compare the output data of the detector 115 to at least one of the models to generate the ellipsometry measurement. The analysis device 120 can also produce a spectroscopic graph based on the at least one ellipsometry measurement. FIG. 3 depicts an example of such a spectroscopic graph 300 that can be generated by the analysis device 120 of the system 100 of FIG. 1. Referring now to FIG. 3, among others, the graph 300 can include a data plot showing the ratio of amplitude diminutions (represented by Ψ) or the phase difference from reflection (represented by A) along the y-axis. Wavelength of the reflected light 240 is shown along the x-axis. The graph shown in the output 300 is illustrative, and in practice may have different shapes depending on the characteristics of the lithium deposit 230. The shape of the graph 300 can depend on the characteristics of the lithium deposit 230 as well as the characteristics of the polarized light 235. For example, features of the graph 300, such as the base width of each peak (represented, e.g., by the width 305), as well as the intensity, position (e.g., wavelength), and distance from surrounding peaks (represented, e.g., by the peak-to-peak distance 310) may correspond variously to the presence or absence of the lithium deposit 230, as well as to the morphology, thickness, microstructure, uniformity, anisotropy, and any other characteristics of the lithium deposit 230. The analysis device 120 can produce the output 300 such that the peak-to-peak resolution is about 20 nanometers.

Although the detector 115 and the analysis device 120 are depicted as separate items and their functions described separately herein, the detector 115 and the analysis device 120 can be combined into a single device. For example, functionality described as being performed by either the detector 115 or the analysis device 120 may be performed by a single device. As described above, the light source 110 and the detector 115 may together form an ellipsometry device. The analysis device 120 may also be formed integrally with such an ellipsometry device. Thus, the ellipsometry device may be a single device or any combination of devices configured to perform functionality described herein in connection with the light source 110, the detector 115, or the analysis device 120.

The analysis device 120 can correlate an ellipsometry measurement (which may be represented by a feature of the graph 300) with results obtained through other techniques, such as microscopy, to generate a library that attributes various features of the graph 300 to various characteristics of the lithium deposit 230 that tend to coincide with particular features of the graph 300. This process can be referred to herein as fingerprinting. For example, the analysis device 120 can cross-reference characteristics of the lithium deposit 230 that may be known based on microscopy data with features of the graph 300 to correlate specific characteristics of the lithium deposit 230 with corresponding features of the graph 300. The analysis device 120 may store these correlations can be in a library or memory data structure that may reside within the analysis device 120. The library can be referenced in the future when the system 100 is used to test other battery cells to allow the results of such tests to be used to determine the specific characteristics of lithium deposits that may form on those cells. Therefore, the system 100, along with the library data, can be used to determine the characteristics of lithium deposits without the need for additional microscopy or spectroscopy techniques (e.g., Raman spectroscopy, Fourier-transform, or infrared spectroscopy). This can be advantageous because such additional microscopy and spectroscopy techniques can be complex, time-consuming and expensive to implement, and may not be compatible with in-situ testing of a battery cell such as the battery cell 105. Thus, ellipsometry, which can characterize thin films, can instead be used in the system 100 to characterize the metal platings, such as the lithium deposit 230, on a powder-based, porous lithium ion electrode, such as the anode 220.

In addition to correlating ellipsometry measurements or spectroscopic graphs such as the spectroscopic graph 300 with results obtained through other methods, the analysis device 120 can also correlate this information with information received from the multimeter 130 and the thermometer 135. For example, the multimeter 130 can include any type of instrument capable of measuring one or more electrical characteristics of the charging circuit 125. The multimeter may be or may include an ammeter to measure a current applied by the charging circuit 125, a voltmeter to measure a voltage applied by the charging circuit 125, or an ohmmeter to measure an electrical load coupled with the charging circuit 125 (e.g., an electrical resistance corresponding to the battery cell 105). The thermometer 135 can determine a temperature measurement taken at a portion of the battery cell 105. For example, the thermometer 135 can measure the temperature at the transparent conductor layer 225 or the anode 220 of the battery cell 105. The thermometer 135 can measure an ambient temperature near the battery cell 105, rather than a temperature of the battery cell 105 itself. For example, the thermometer 135 can measure the air temperature in the environment surrounding the battery cell 105. The analysis device 120 can use the information received from the multimeter 130 and the thermometer 135, along with information corresponding to the graph 300 or the fingerprinting library, to determine a correlation between the electrical conditions (e.g., corresponding to information received from the multimeter 130) or environmental conditions (e.g., corresponding to information received from the thermometer 135) and the characteristics of lithium deposits that form under these electrical and environmental conditions.

The analysis device 120 can also use information included in the graph 300 (e.g., an ellipsometry measurement) or in the fingerprinting library to select at least one design parameter for a battery cell other than the battery cell 105. The design parameter can include a physical design parameter, such as a size or shape or any portion of the battery cell (e.g., an anode of the battery cell). The design parameter can also include a parameter relating to environmental or electrical conditions selected for charging or operating the battery cell. The other battery cell for which the design parameter can be selected can be a battery cell for use in an electric vehicle. For example, the other battery cell for which the design parameter is selected can be a battery cell configured to be included within a battery pack that includes multiple battery cells and is installed in an electric vehicle to provide electrical power for the electric vehicle.

The analysis device 120 can select the design parameter to minimize or reduce a likelihood that a lithium deposit such as the lithium deposit 230 will develop on an anode of the battery cell. For example, the analysis device 120 can determine that an ellipsometry measure, the graph 300, or the fingerprinting library suggests lithium plating has an elevated risk of occurring when a battery cell is charged faster than a threshold charging rate (i.e., using a current above a threshold current). As a result, the analysis device 120 can select the threshold current as a design parameter corresponding to an upper limit of a current for charging a battery cell. Stated differently, the analysis device 120 can determine a correlation between an ellipsometry measure, the graph 300, or the fingerprinting library and the rate of charging of the battery cell, and can therefore determine the design parameter based on this correlation. In another example, the analysis device 120 can determine a correlation between an ellipsometry measure, the graph 300, or the fingerprinting library and the temperature measurement produced by the thermometer 135. The correlation may suggest that lithium plating has an elevated risk of occurring when a battery cell is charged in an environment in which the ambient temperature exceeds a threshold temperature. As a result, the analysis device 120 can select the threshold temperature as a design parameter corresponding to an upper limit of a temperature in which the battery cell should be charged.

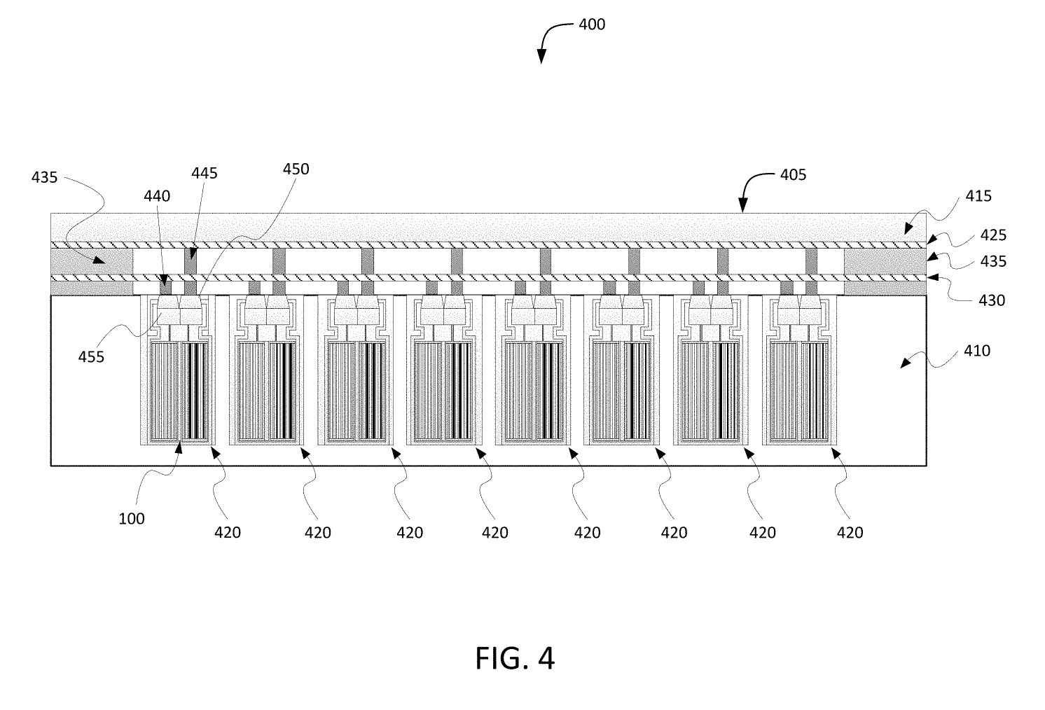

FIG. 4 depicts as example cross-section view 400 of a battery pack 405 to hold a plurality of battery cells 100 in an electric vehicle. The battery pack 405 can include a battery module case 410 and a capping element 415. The battery module case 410 can be separated from the capping element 415. The battery module case 410 can include or define a plurality of holders 420. Each holder 420 can include a hollowing or a hollow portion defined by the battery module case 410. Each holder 420 can house, contain, store, or hold a battery cell 105. The battery module case 410 can include at least one electrically or thermally conductive material, or combinations thereof. The battery module case 410 can include one or more thermoelectric heat pumps. Each thermoelectric heat pump can be thermally coupled directly or indirectly to a battery cell 105 housed in the holder 420. Each thermoelectric heat pump can regulate temperature or heat radiating from the battery cell 105 housed in the holder 420. Bonding elements 450 and 455, which can each be electrically coupled with a respective one of the cathode 210 and the anode 220 of the battery cell 105, can extend from the battery cell 105 through the respective holder 420 of the battery module case 410.

Between the battery module case 410 and the capping element 415, the battery pack 405 can include a first busbar 425, a second busbar 430, and an electrically insulating layer 435. The first busbar 425 and the second busbar 430 can each include an electrically conductive material to provide electrical power to other electrical components in the electric vehicle. The first busbar 425 (or first current collector) can be connected or otherwise electrically coupled with the first bonding element 450 extending from each battery cell 105 housed in the plurality of holders 420 via a bonding element 445. The bonding element 445 can be bonded, welded, connected, attached, or otherwise electrically coupled with the bonding element 450. For example, the bonding element 445 can be welded onto a top surface of the bonding element 450. The second busbar 430 (or second current collector) can be connected or otherwise electrically coupled with the second bonding element 455 extending from each battery cell 105 housed in the plurality of holders 420 via a bonding element 440. The bonding element 440 can be bonded, welded, connected, attached, or otherwise electrically coupled with the second bonding element 455. For example, the bonding element 440 can be welded onto a top surface of the second bonding element 455. The second busbar 430 can define the second polarity terminal for the battery pack 405.

The first busbar 425 and the second busbar 430 can be separated from each other by the electrically insulating layer 435. The electrically insulating layer 435 can include spacing to pass or fit the first bonding element 450 connected to the first busbar 425 and the second bonding element 455 connected to the second busbar 430. The electrically insulating layer 435 can partially or fully span the volume defined by the battery module case 410 and the capping element 415. A top plane of the electrically insulating layer 435 can be in contact or be flush with a bottom plane of the capping element 415. A bottom plane of the electrically insulating layer 435 can be in contact or be flush with a top plane of the battery module case 410. The electrically insulating layer 435 can include any electrically insulating material or dielectric material, such as air, nitrogen, sulfur hexafluoride (SF₆), porcelain, glass, and plastic (e.g., polysiloxane), among others to separate the first busbar 425 from the second busbar 430.

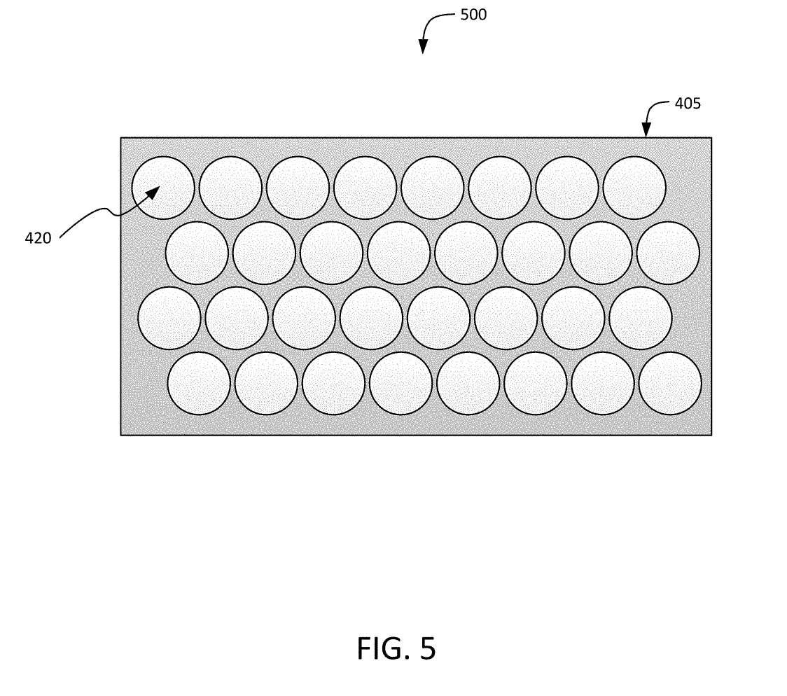

FIG. 5 depicts a top-down view 500 of a battery pack 405 to a hold a plurality of battery cells 100 in an electric vehicle. The battery pack 405 can define or include a plurality of holders 420. The shape of each holder 420 can be triangular, rectangular, pentagonal, elliptical, and circular, among others. The shapes of each holder 420 can vary or can be uniform throughout the battery pack 405. For example, some holders 420 can be hexagonal in shape, whereas other holders can be circular in shape. The shape of the holder 420 can match the shape of a housing of each battery cell 105 contained therein. The dimensions of each holder 420 can be larger than the dimensions of the battery cell 105 housed therein.

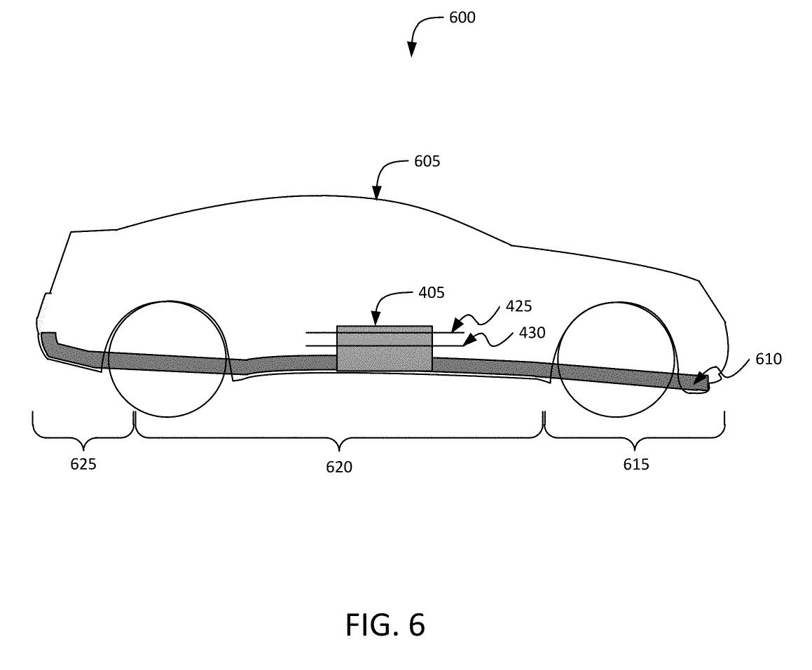

FIG. 6 depicts a cross-section view 600 of an electric vehicle 605 installed with a battery pack 405. The electric vehicle 605 can include a chassis 610 (sometimes referred to as a frame, internal frame, or support structure). The chassis 610 can support various components of the electric vehicle 605. The chassis 610 can span a front portion 615 (sometimes referred to a hood or bonnet portion or the portion of the electric vehicle 605 from the front wheel wells to the front bumper), a body portion 620 (e.g., between the front and rear wheel wells), and a rear portion 625 (sometimes referred to as a trunk portion or the portion of the electric vehicle 605 from the rear wheel wells to the rear bumper) of the electric vehicle 605. The battery pack 405 can be installed or placed within the electric vehicle 605. The battery pack 405 can be installed on the chassis 610 of the electric vehicle 605 within the front portion 615, the body portion 620 (as depicted in FIG. 6), or the rear portion 625. The first busbar 425 and the second busbar 430 can be connected or otherwise be electrically coupled with other electrical components of the electric vehicle 605 to provide electrical power.

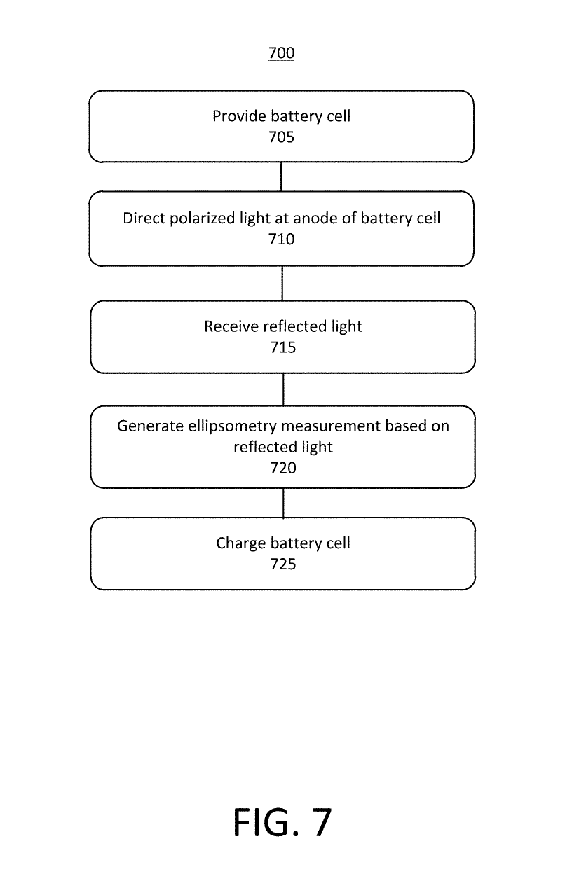

FIG. 7 is a flow diagram depicting an example method 700 of evaluating lithium plating on anodes of battery cells, according to an illustrative implementation. The functionalities of the method 700 can be implemented or performed using any of the systems, apparatuses, or battery cells detailed above in connection with FIGS. 1-6. In brief overview, the method 700 can include providing a battery cell (ACT 705). The method 700 can include directing polarized light at an anode of the battery cell (ACT 710). The method 700 can include receiving reflected light (ACT 715). The method 700 can include generating an ellipsometry measurement based on the reflected light (ACT 720). The method 700 can include charging the battery cell (ACT 725).

Referring again to FIG. 7, among others, the method 700 can include providing a battery cell (ACT 705). The battery cell can be similar to the battery cell 105 shown in FIGS. 1 and 2. For example, the battery cell 105 can include an aluminum layer 205. The aluminum layer 205 can be a part of a housing of the battery cell 105. The battery cell 105 can include a cathode 210 in contact with the aluminum layer 205. The battery cell 105 can include an anode 220. The cathode 210 and the anode 220 can each be in contact with a separator 215. The separator 215 can be formed from an electrically insulating material and can electrically insulate the cathode 210 from the anode 220. The battery cell 105 can also include a transparent conductor 225 that can be in contact with the anode 220. The transparent conductor 225 can be any type or form of electrically conductive material configured to be at least partially transparent to light. For example, the transparent conductor 225 can be or can include fluorinated tin oxide. The transparent conductor 225 may cover only a portion of a surface of the anode 220.

The method 700 can include directing polarized light at the anode of the battery cell (ACT 710). The polarized light can be generated, for example, by a light source such as the light source 110 Shown in FIGS. 1 and 2. The light produced by the light source 110 can be passed through a polarizer to give the light a specific angle. The polarizer can be included as an integral component of the light source 110. The light source 110 can be operated continuously such that polarized light is directed at the anode 220 over a period of time. The polarized light can include visible light, infrared light, ultraviolet light, or light from any other portion of the electromagnetic spectrum. The polarized light can also include broad spectrum polarized light. For example, the polarized light can include a combination of visible, infrared, and ultraviolet light. Therefore the light source 110 can be configured to scan the polarized light 235 along a length of the anode 220 to increase a probability that the polarized light 235 will contact any lithium deposits such as the lithium deposit 230 that may be present on the anode 220. The polarized light can be directed towards the anode 220 at a first angle with respect to a surface of the anode 220.

The anode 220 can reflect the polarized light to produce reflected light. The method 700 can include receiving the reflected light (ACT 715). A detector, such as the detector 115 shown in FIGS. 1 and 2, can be configured to receive the reflected light. The detector 115 can be any type of photodetector capable of detecting a presence of the reflected light, as well as one or more characteristics of the reflected light. For example, the detector 115 can determine any combination of a wavelength, a frequency, or a polarization of the reflected light. The detector 115 can also be configured to generate an output signal representing at least one of these characteristics. For example, the detector 115 can be configured to produce output data that correlates the characteristics of the polarized light 235 with those of the reflected light 240 over time, and the correlation can be plotted graphically.

The method 700 can include generating an ellipsometry measurement based on the reflected light (ACT 720). An analysis device such as the data analysis device 120 shown in FIGS. 1 and 2 can be configured to generate the ellipsometry measurement. The analysis device 120 can be configured to receive output data generated by the detector 115 that receives the reflected light (ACT 715). The data analysis device 120 and the detector 115 can also be implemented as a single integrated device. For example, a single device can perform detection functionality similar to ACT 715, as well as ellipsometry measurement functionality. The ellipsometry measurement can relate to any change of polarization of the reflected light relative to the polarized light that was directed at the anode 220 in ACT 710 of the method 700.

The data analysis device 120 can generate the ellipsometry measurement based on one or more models. For example, the analysis device 120 may store information corresponding to one or more models and can be configured to compare the output data from the detector 115 to at least one of the models to generate the ellipsometry measurement. The analysis device 120 can also be configured to produce a spectroscopic graph based on the at least one ellipsometry measurement. For example, the data analysis device 120 can be configured to produce a graph formatted in a manner similar to that shown in FIG. 3. The ellipsometry measurement can be or can include a measurement related to a characteristic of such a spectroscopic graph. For example, the ellipsometry measurement can refer to characteristics of the graph such as the base width of each peak, as well as an intensity, a position, and a distance of a peak from surrounding peaks. The data analysis device 120 can also be configured to correlate the ellipsometry measurement with a presence or absence of a lithium deposit present on the anode 220, as well as the morphology, thickness, microstructure, uniformity, anisotropy, and any other characteristics of such a lithium deposit.

The method 700 can include charging the battery cell (ACT 725). This can be done, for example, by the charging circuit 125 shown in FIGS. 1 and 2. The charging circuit 125 can be configured to charge the battery cell 105 continuously while the polarized light is directed at the anode 220 of the battery cell 105 (ACT 710). The charging circuit 125 can charge the battery cell 105 by applying an electric potential (i.e., a voltage) across the cathode 210 and the anode 220 to cause lithium ions to move from the cathode to the anode, where they can be stored until the battery cell 105 is discharged. The charging circuit 125 can be configured to charge the battery cell 105 using a variety of electrical charging parameters, including different applied currents or voltages. Environmental conditions, such as ambient temperature, also can be varied while the charging circuit 125 charges the battery cell 105.

The data analysis device 120 can correlate the ellipsometry measurement with any of these electrical or environmental characteristics to determine whether any particular range of electrical or environmental characteristics is associated with an ellipsometry measurement that indicates the presence of a lithium deposit on the anode 220 of the battery cell 105. The data analysis device 120 can use this information to determine at least one parameter of another battery cell, such as maximum current or voltage that should be used to charge the battery cell to reduce a likelihood that the battery cell will develop a lithium deposit as a result of the charging, or a minimum ambient temperature, a maximum ambient temperature, or a range of ambient temperatures under which the battery cell should be charged to reduce a likelihood that the battery cell will develop a lithium deposit during the charging process, as described above.

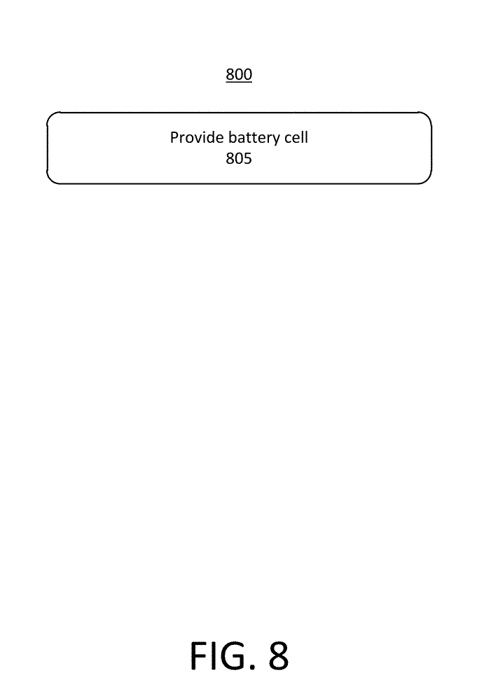

FIG. 8 is a flow diagram depicting an example method 800 of evaluating lithium plating on anodes of battery cells, according to an illustrative implementation. The method 800 can include providing a system to characterize lithium plating on anodes of battery cells (ACT 805). The system can include a battery cell having an aluminum layer, a cathode in contact with the aluminum layer, an anode formed from a powder-based, porous material, a separator layer in contact with the cathode and the anode to electrically insulate the cathode from the anode, and a transparent conductor layer electrically coupled with the anode. The system can include a light source to direct polarized light at a first angle with respect to a surface of the anode through the transparent conductor layer of the battery cell toward the anode to cause the anode to reflect the polarized light to produce reflected light directed at a second angle with respect to the surface of the anode. The system can include a detector to receive the reflected light and to generate an ellipsometry measurement based on the reflected light. The system can include a charging circuit to charge the battery cell while the light source directs the polarized light through the transparent conductor layer of the battery cell toward the anode of the battery cell.

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. Features that are described herein in the context of separate implementations can also be implemented in combination in a single embodiment or implementation. Features that are described in the context of a single implementation can also be implemented in multiple implementations separately or in various sub-combinations. References to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any act or element may include implementations where the act or element is based at least in part on any act or element.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

The systems and methods described herein may be embodied in other specific forms without departing from the characteristics thereof. For example, descriptions of positive and negative electrical characteristics may be reversed. For example, elements described as negative elements can instead be configured as positive elements and elements described as positive elements can instead by configured as negative elements. Further relative parallel, perpendicular, vertical or other positioning or orientation descriptions include variations within +/−10% or +/−10 degrees of pure vertical, parallel or perpendicular positioning. References to “approximately,” “substantially” or other terms of degree include variations of +/−10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

1. A system to evaluate lithium plating on anodes of battery cells, comprising:
a battery cell having an aluminum layer, a cathode in contact with the aluminum layer, an anode formed from a powder-based, porous material, a separator layer in contact with the cathode and the anode to electrically insulate the cathode from the anode, and a transparent conductor layer electrically coupled with the anode;
a light source to direct polarized light at a first angle with respect to a surface of the anode through the transparent conductor layer of the battery cell toward the anode to cause the anode to reflect the polarized light to produce reflected light directed at a second angle with respect to the surface of the anode;
a detector to:
receive the reflected light; and
generate an ellipsometry measurement based on the reflected light; and
a charging circuit to charge the battery cell while the light source directs the polarized light through the transparent conductor layer of the battery cell toward the anode of the battery cell.

2. The system of claim 1, comprising:
a sample holder to secure the battery cell in a fixed position and a fixed orientation.

3. The system of claim 1, comprising:
the anode formed from graphite.

4. The system of claim 1, comprising:
the transparent conductor layer formed from fluorinated tin oxide.

5. The system of claim 1, comprising:
a data analysis device to determine a characteristic of a lithium deposit on the anode based on the ellipsometry measurement, the characteristic corresponding to at least one of a morphology of the lithium deposit, a thickness of the lithium deposit, a microstructure of the lithium deposit, a uniformity of the lithium deposit, and an anisotropy of the lithium deposit.

6. The system of claim 1, comprising:
a data analysis device to:
produce a spectroscopic graph based on the ellipsometry measurement; and
determine a characteristic of a lithium deposit on the anode, based on at least one of a peak-to-peak distance of the spectroscopic graph and a width of a base of a peak of the spectroscopic graph.

7. The system of claim 1, comprising:
an ammeter to measure a rate of charging of the battery cell; and
a data analysis device to determine a correlation between the ellipsometry measurement and the rate of charging of the battery cell.

8. The system of claim 1, comprising:
a thermometer to measure an ambient temperature at the transparent conductive layer; and
a data analysis device to determine a correlation between the ellipsometry measurement and the ambient temperature at the transparent conductive layer.

9. The system of claim 1, comprising:
the charging circuit to overcharge the battery cell while the light source directs the polarized light through the transparent conductor layer of the battery cell towards the anode of the battery cell.

10. The system of claim 1, comprising:
a lithium deposit on the anode having a thickness of between 5 nanometers and 25 microns.

11. The system cell of claim 1, wherein the battery cell is part of a battery pack that includes a plurality of additional battery cells.

12. The battery cell of claim 1, wherein the battery cell is part of a battery pack that includes a plurality of additional battery cells disposed in an electric vehicle.

13. A method of analyzing lithium plating on anodes of battery cells, comprising:
providing a battery cell having an aluminum layer, a cathode in contact with the aluminum layer, an anode formed from a powder-based, porous material, a separator layer in contact with the cathode and the anode to electrically insulate the cathode from the anode, and a transparent conductor layer electrically coupled with the anode;
directing polarized light from a light source at a first angle with respect to a surface of the anode through the transparent conductor layer of the battery cell toward the anode to cause the anode to reflect the polarized light to produce reflected light directed at a second angle with respect to the surface of the anode;
receiving, by a detector, the reflected light;
generating, by the detector, an ellipsometry measurement based on the reflected light; and
charging, by a charging circuit, the battery cell while the light source directs the polarized light through the transparent conductor layer of the battery cell toward the anode of the battery cell.

14. The method of claim 13, comprising:
determining, by a data analysis device, a characteristic of a lithium deposit on the surface of the anode, based on the ellipsometry measurement, the characteristic corresponding to at least one of a morphology of the lithium deposit, a thickness of the lithium deposit, a microstructure of the lithium deposit, a uniformity of the lithium deposit, and an anisotropy of the lithium deposit.

15. The method of claim 13, comprising:
producing, by a data analysis device, a spectroscopic graph based on the ellipsometry measurement; and
determining, by the data analysis device, a characteristic of a lithium deposit on the surface of the anode, based on at least one of a peak-to-peak distance of the spectroscopic graph and a width of a base of a peak of the spectroscopic graph.

16. The method of claim 13, comprising:
measuring, by an ammeter, a rate of charging of the battery cell; and
determining, by a data analysis device, a correlation between the ellipsometry measurement and the rate of charging of the battery cell.

17. The method of claim 13, comprising:
measuring, by a thermometer, an ambient temperature at the transparent conductive layer; and
determining, by a data analysis device, a correlation between the ellipsometry measurement and the ambient temperature at the transparent conductive layer.

18. The method of claim 13, wherein the battery cell is a first battery cell, comprising:
selecting, based on the ellipsometry measurement, a design parameter for a second battery cell, the second battery cell included in a battery pack to power an electric vehicle.

19. The method of claim 13, comprising:
overcharging, by the charging circuit, the battery cell while the ellipsometer directs the polarized light through the transparent conductor layer of the battery cell towards the surface of the anode of the battery cell.

20. A method, comprising:
providing a system to detect lithium plating on anodes of battery cells, comprising:
a battery cell having an aluminum layer, a cathode in contact with the aluminum layer, an anode formed from a powder-based, porous material, a separator layer in contact with the cathode and the anode to electrically insulate the cathode from the anode, and a transparent conductor layer electrically coupled with the anode;
a light source to direct polarized light at a first angle with respect to a surface of the anode through the transparent conductor layer of the battery cell toward the anode to cause the anode to reflect the polarized light to produce reflected light directed at a second angle with respect to the surface of the anode;
a detector to:
receive the reflected light; and
generate an ellipsometry measurement based on the reflected light; and
a charging circuit to charge the battery cell while the light source directs the polarized light through the transparent conductor layer of the battery cell toward the anode of the battery cell.
